(19) United States
(12) Patent Application Publication
(10) Pub. No.: US 2025/0085699 A1
(43) Pub. Date: Mar. 13, 2025

(54) SUBSTRATE MANUFACTURING EQUIPMENT COMPREHENSIVE DIGITAL TWIN FLEET

(71) Applicant: Applied Materials, Inc., Santa Clara, CA (US)

(72) Inventors: Adolph Miller ALLEN, Oakland, CA (US); Karthik RAMANATHAN, Bangalore (IN); Girish VENKATACHALAPATHY, Alzenau (IN); Umesh M. KELKAR, Santa Clara, CA (US); Kasturi Tulashidas SARANG, San Jose, CA (US); Yimeng LYU, Mountain View, CA (US); Weize HU, Sunnyvale, CA (US); Ying TENG, Pacheco, CA (US); Sejune CHEON, Seoul (KR); Shiqi DONG, Milpitas, CA (US); Paul Gerard KIELY, Santa Cruz, CA (US); Milan PRAKASH, Bangalore (IN)

(21) Appl. No.: 18/244,104

(22) Filed: Sep. 8, 2023

(51) Int. Cl. G05B 19/418; H01L 21/67

(52) U.S. Cl. CPC G05B 19/41885; H01L 21/67276; G05B 2219/42155

(57) ABSTRACT

A method, apparatus, and system for controlling a physical twin chamber configured to process substrates are described herein. In some embodiments, a method comprises determining, by a digital twin device, characteristics of a physical twin chamber and generating control inputs for controlling the physical twin chamber. The digital twin device comprises one or more computational models for determining the characteristics of the physical twin and for generating the control inputs. The digital twin device determines a first data set associated with the physical twin chamber. The first data set comprises process data collected by sensors configured to measure attributes of the physical twin chamber. Based on the first data, the digital twin device automatically generates a second data set based on the generated control inputs and transmits the second data set to the physical twin chamber for controlling the process performed on the substrates by the physical twin chamber.

### FIELD

Embodiments of the disclosure generally relate to an apparatus and method of processing a substrate.

### BACKGROUND

Substrate manufacturing methods, as well as related tools and physical chambers, employ a wide variety of physical and chemical processes. Examples of the processes may include depositing films onto the corresponding media, controlling the way the materials are deposited, and modifying the depositing processes to ensure their accuracy. The functionality and repeatability of the processes are predicated on the processes' accuracy, precision, and reliability, which in turn are taken into consideration in the design, operation, and control of the devices used in substrate manufacturing.

Substrate manufacturing devices are usually operated and controlled by hardware, firmware, software, or any combination thereof. Designing the devices usually starts with defining a physical chamber hardware and software configuration; then determining a start-up configuration and chamber calibration parameters; following up with engineering and maintaining the devices that are expected to effectively and precisely manufacture the substrates.

A physical chamber usually includes thousands of parts and many electro-mechanical subsystems for controlling the physical processes designed to perform substrate manufacturing. The chamber typically receives many key input recipe parameters that are then applied to multiple recipe steps executed by the chamber's processes. However, many of the subsystems may exhibit transient responses to the input parameters due to, for example, the changes in the physical states of the chamber's components or a drift in one or more of their physical attributes over time. This may make the managing and calibrating of the chambers, their components, and their processes quite challenging.

Some of the above-described issues may be resolved using control systems for monitoring and controlling the chambers' processes involved in substrate manufacturing. The tools may allow, for example, monitoring of the warnings or faults related to system hardware and limits on values such as power, voltage, current, or temperature, related to control instructions for managing the substrate manufacturing processes, and the like. However, the delay between the time when the anomalies are observed and the time when the corrective instructions are implemented in a physical chamber may be sometimes unacceptable. Furthermore, performing this type of monitoring may be often time-consuming, and correcting the corresponding defects may be labor-intensive.

Accordingly, there is a need to develop a framework for automatically tracking and controlling the chamber performance over time.

### SUMMARY

Methods, apparatus, and systems for controlling a physical twin chamber configured to manufacture substrates are described herein.

In some embodiments, a method comprises receiving, by a digital twin device, via one or more communications interfaces, a first data set associated with a physical twin chamber.

Generally, a digital twin is a computational model (or a set of coupled computational models) that evolves to persistently represent the structure, behavior, and context of a unique physical asset such as a component, system, or process. In the context of this disclosure, a digital twin device is a device configured to capture and model characteristics and processes of the physical twin chamber and generate control inputs for controlling the physical twin chamber. The digital twin device may also be configured to model the characteristics and properties of the substrate that is processed by the physical twin. The characteristics and processes of physical chambers, chambers' processes, substrates, and the like may be captured in the corresponding models.

The models of digital twin devices may be built based on the physical models of the physical twins, the physical models of the processes executed in the physical twins, the physical models of the substrates, the interactions between the processes executed in the physical twins, the reactions occurring in the substrates, and the like. The models of the digital twin devices may be also built based on statistical/AI/ML models and hybrid models that combine physics and data.

One of the aspects of the models executed by digital twin devices is that the models may be built based on the skillful designs of the corresponding possible models of the physical components and can include physics models, statistics models, AI/ML, hybrid, and the like. The effectiveness of the physical models allows the rapid and fast execution of the corresponding models by the digital twin devices. In some implementations, certain digital models may be executed by a digital twin device within a fraction, or so.

A digital twin device may include various computational models, components, and subsystems for modeling characteristics and processes and for generating control inputs. Communications between the digital twin device and a physical twin chamber may be facilitated using communications interfaces. The data communicated to the digital twin device (also referred to as a first data set) may include direct measurements of physical processes collected and reported by probes and sensors implemented in the physical twin chamber, data collected and reported by internal sensors of the digital twin device, data collected and reported by sensors monitoring substrates, and the like.

In some embodiments, the method comprises automatically generating, by the digital twin device, a second data set that comprises the control inputs, and transmitting the second data set, by the digital twin device, to the physical twin chamber for controlling the manufacturing of substrates by the physical twin chamber. The second data set is automatically generated by the digital twin device based on, at least in part, the first data set, and by executing one or more computational models, components, and subsystems of the digital twin device.

A digital twin apparatus for controlling a physical twin chamber comprises a digital twin device capturing and modeling characteristics and processes of a physical twin chamber and generating control inputs for controlling the physical twin chamber. The digital twin device comprises computational models, components, and subsystems for modeling the characteristics and processes and generating control inputs. The interfaces facilitate communications between the digital twin device and the physical twin chamber.

In some embodiments, the digital twin device receives, via communications interfaces, the first data set associated with the physical twin chamber. The first data set comprises direct measurement of physical processes collected and reported by probes and sensors implemented in the physical twin chamber, data collected and reported by internal sensors of the digital twin device, and the like. Based on the first data set, the digital twin device automatically generates the second data set that comprises the control inputs and transmits the second data set to the physical twin chamber for controlling the manufacturing of substrates by the physical twin chamber. The second data set is automatically generated by the digital twin device by executing computational models, components, and subsystems of the digital twin device.

A substrate processing system comprises a digital twin device capturing and modeling characteristics and processes of a physical twin chamber and generating control inputs for controlling the physical twin chamber. The digital twin device comprises example models described above, components, and subsystems for modeling the characteristics and the processes, and the like, and for generating the control inputs.

In some embodiments, the substrate processing system comprises one or more communications interfaces facilitating communications between at least the digital twin device and the physical twin chamber. The interfaces facilitate communications between the digital twin device and the physical twin chamber.

The digital twin device comprises a processor and memory coupled to the processor. The memory may have stored instructions executable by the processor to, for example, receive, by the digital twin device, via one or more communications interfaces, a first data set associated with a physical twin chamber. The first data set comprises direct measurement of physical processes collected and reported by probes and sensors implemented in the physical twin chamber and data collected and reported by internal sensors of the digital twin device. In some embodiments, the memory has stored instructions executable by the processor to automatically generate, by the digital twin device, a second data set that comprises the control inputs, and transmit the second data set, by the digital twin device, to the physical twin chamber for controlling the manufacturing of substrates by the physical twin chamber. The second data set is automatically generated by the digital twin device based on, at least in part, the first data set, and by executing computational models, components, and subsystems of the digital twin device.

In some embodiments, a method comprises automatically determining, by each digital twin device a first data set associated with a corresponding process chamber of process chambers. The plurality of digital twin devices captures and models characteristics and processes of process chambers and generates control inputs for controlling the process chambers or processes executed by the chambers during the manufacturing of substrates. The method further comprises automatically generating, by each digital twin device, a second data set that comprises control inputs, and automatically transmitting the second data set to the process chamber.

In some embodiments, a method comprises determining, by each digital twin device, of a plurality of digital twin devices, a first data set associated with at least one process chamber of a plurality of chamber processes, and the corresponding processes for processing a plurality of substrates. Each digital twin device comprises one or more computational models. The first data set comprises measurements reported by probes or sensors within the at least one chamber process, or data collected and reported by internal sensors of the digital twin device. The method further automatically generating, by each digital twin device a second data set based on, at least in part, the first data set, and by executing one or more computational models of the digital twin device.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is an example graphical representation of a digital-physical twin pair according to some embodiments of the present principles.

FIG. 2 is an example graphical representation of a thermal digital-physical twin pair according to some embodiments of the present principles.

FIG. 3 is an example coupled system of a physical and digital twin for processing substrates according to some embodiments of the present principles.

FIG. 4 is an example coupled system of physical and digital twins for multiple processes performed in a time sequence according to some embodiments of the present principles.

FIG. 5 is an example coupled system of physical and digital twins for multiple processes for processing substrates according to some embodiments of the present principles.

FIG. 6 is an example of a coupled system of multiple physical and digital twins for multiple processes performed in a time sequence according to some embodiments of the present principles.

FIG. 7 is an example dynamic decision network according to some embodiments of the present principles.

FIG. 8 is an example architecture of a thermal digital twin according to some embodiments of the present principles.

FIG. 9 is an example architecture of a thermal digital twin for substrate processing according to some embodiments of the present principles.

FIG. 10 is an example of a flow digital twin according to some embodiments of the present principles.

FIG. 11 is an example process executed by a digital twin device of a digital-physical twin pair according to some embodiments of the present principles.

FIG. 12 is an example process executed by a digital twin device of a physical and digital twin for multiple processes for processing substrates according to some embodiments of the present principles.

FIG. 13 is an example process executed by a digital twin device of a physical and digital twin for multiple processes performed in a time sequence according to some embodiments of the present principles.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, numerous specific details are outlined to provide a thorough understanding of the present approach. It will be apparent, however, that the present approach may be practiced without these specific details. In other instances, well-known structures and devices are shown in block diagram form to avoid unnecessarily obscuring the present approach.

Embodiments of the present principles relate to a comprehensive digital twin device, or a digital twin fleet, for controlling substrate manufacturing process operations performed by one or more physical twin chambers. The principles are applicable in, for example, semiconductor (e.g., wafer or substrate) manufacturing systems. The principles may be implemented in a pair of a digital twin device and a physical twin chamber, or a fleet of physical/digital twin pairs, each having interdependent sub-assemblies and components.

Substrate manufacturing techniques are usually quite complex and may include, for example, etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed laser deposition (PLD), molecular layer deposition (MLD), plasma enhanced molecular layer deposition (PEMLD), conformal film deposition (CFD), plasma enhanced pulsed deposition layer (PEPDL) processing, implant, and resist removal. Due to their complexity, the physical chambers used in substrate manufacturing may be difficult to control and manage.

### Example Physical Twin Chambers

Before the digital twin concept is described, a brief description of a typical physical twin chamber is provided herein. Describing the physical chamber illustrates some of the technical problems related to controlling and managing the processes and components of the physical chamber and illustrates some of the technical solutions based on the use of a digital twin, which is described later.

A physical twin chamber, or a system of physical twin chambers, is a physical device that is configured to process a substrate. The processing may include depositing films onto a substrate to form integrated semiconductor devices, and the like. Unless otherwise specified, the term “physical twin chamber” refers to a physical device such as a process chamber, a cluster tool, one or more process chambers or cluster tools, or a physical component that can be used in combination with a digital twin as described herein. In some portions of the disclosure provided herein, the phrase “physical twin chamber” has been shortened to “physical twin” to avoid any confusion regarding the physical twin chamber being an actual process chamber, cluster tool, or one or more process chambers or cluster tools versus a physical component, such as a substrate or other similar type of processed or processing component that can be used in combination with a digital twin.

Processing semiconductors is a rather complex process and the way the substrates or films are formed on the substrate usually involves precise monitoring and controlling of process parameters. For example, the data associated with substrate manufacturing need to be closely monitored and various processing issues need to be efficiently resolved during the processing. Examples of the issues may relate to film metrology data, such as sheet resistance (Rs), film thickness, film stress, refractive index, and hardness, as well as feature scale data such as critical dimension (CD), uniformity, line edge roughness (LER), sidewall coverage, and bottom coverage. These and many other issues need to be monitored to ensure the accurate performance of the physical chambers.

A physical chamber usually includes thousands of parts and many major electro-mechanical subsystems controlling physical processes for managing, for example, electrical signals, gas flow, pressure/vacuum, power delivery, and chamber and substrate temperature. There are commonly at least ten or more key input recipe parameters applied over multiple recipe steps. Many of the subsystems may also exhibit transient responses during one or more of the recipe steps due to physical state changes or drift over time.

The significance of the problems with physical chambers may be described using, for example, a reference to sheet-resistance (Rs) drifts in the film layer deposited on substrates processed within a physical chamber configured to sequentially manufacture substrates therein. Typically, during a CVD deposition process, the tantalum nitride (TaN) layer is deposited on a showerhead (SH) and substrate. During the process, the emissivity of the SH increases, which may cause a reduction in the substrate process temperature as the number of processed substrates in the physical chamber increases. That in turn can cause a drift in the Rs of the film layer formed on the processed substrates as the number of processed substrates in the physical chamber increases.

In the above example, based on various empirical measurements taken from a processed substrate every two days, about 1.3% system uptime loss was observed due to the need to correct the Rs drift problem. Correcting the drift in sheet-resistance Rs using conventional approaches is usually difficult because correcting the drift based on the conventional ex-situ process sampling techniques often leads to, for example, delaying the detection of the drift, causing device yield issues, substrate scrap, and the like.

Physical chambers are usually very complex devices that implement a multitude of complex processes that may be difficult to monitor and control. An example physical twin chamber includes walls, a bottom portion, and a chamber lid that together enclose a susceptor and a processing region. The physical twin chamber may also include a vacuum pump, a gas source, a first radio frequency (RF) generator, a first RF match, a second RF generator, a second RF match, and an RF filter, each coupled externally to the physical twin chamber. An example of a physical chamber is described in, for instance, U.S. Pat. No. 11,570,879.

Based on the above, it is easy to conclude that a physical chamber is a complex system that executes complex substrate manufacturing processes. Controlling the processes and the chamber's components is usually challenging. However, the technical solutions described below that are based on the concept of pairs of digital twin devices and physical twin chambers, provide tools and methodologies for controlling the chamber's processes efficiently and accurately.

### Example Digital Twin Devices

In the context of this disclosure, a digital twin device is a device configured to create a real-time virtual model of a physical twin chamber to allow the direct comparison of the performance of both the physical and digital twins during the operation of the physical twin chamber. The digital twin device may execute a virtual model that can be used asynchronously to model the expected performance of the corresponding physical twin chamber without a need to perform time-consuming and labor-intensive actual experiments or ex-situ testing. In this context, the digital twin device is used as both a predictive tool as well as a diagnostic tool.

A digital twin device may be configured to perform, for example, the process diagnostics, the chamber tuning, and the chamber's process iteration control through the use of virtual experiments performed using a virtual model. Performing these processes is enabled by the incorporation of substrate film metrology, feature scale measurements, and device performance measurements determined for both the physical and digital twins and based on the received inputs.

The digital twin concept can be extended to process chambers, then from process chambers to systems, and then to groups of systems. In the case of multi-process cluster tools, the digital twin concept can be used to link the results of a substrate processing sequence from the performance of each chamber within the processing sequence to processing performed in one or more cluster tools or a series of cluster tools.

In general, a digital twin is a real-time virtual representation of a real-world physical system or process, such as a physical twin. The digital twin may serve as the indistinguishable digital counterpart of a physical twin chamber for certain practical purposes. In the context of this disclosure, the digital twin may be used to perform, for example, a system simulation, integration, testing, monitoring, maintenance, and the like. The digital twin device may be configured to monitor and control the physical twin chamber by executing one or more fast-running network models and empirically built relational data models.

A digital twin device may include one or more processors and one or more memory units coupled to the processors and may be configured to capture and model characteristics and processes of a physical twin chamber. The digital twin may be also configured to generate control inputs for controlling the physical twin chamber. The digital twin device may include computational models, components, and subsystems for modeling the characteristics and the processes, and subsystems for generating the control inputs.

The digital twin device may be configured to receive, via one or more communications interfaces, the first data set associated with a physical twin chamber. The first data set is the input data that comprise direct measurement of physical processes collected and reported by probes and sensors implemented in the physical twin chamber and data collected and reported by internal virtual sensors of the digital twin device. As described later, the first data set corresponds to the input to an application executed by the digital twin device, such as, for example, an artificial intelligence (AI) based application.

Upon receiving the first data set (i.e., the input), the digital twin device may automatically generate the second data set that comprises control instructions. As described later, the second data set corresponds to the output generated by the AI-based application of the digital twin device.

The second data set may be transmitted by the digital twin device to the physical twin chamber for controlling the processing of substrates by the physical twin chamber. The second data set is automatically generated by the digital twin device based on, at least in part, the first data set, and by executing the computational models, components, and subsystems of the digital twin device.

The above-outlined process starts when the digital twin device receives the first data set (i.e., input) from the physical twin chamber, sensors, and the like, and automatically generates/transmits the second data set (i.e., output) for the physical twin chamber. That is performed in real-time or pseudo-real-time. Therefore, the digital twin generates the second data set and transmits the second data set to the physical twin contemporaneously while receiving the first data set from the physical twin chamber. That means that the digital twin generates the second data set (i.e., the control inputs for the physical twin chamber) in real time determined by the receiving of the first data set from the physical twin chamber. The characteristics of the digital twin device and the way that the digital twin device operates distinguish the digital twin device disclosed herein from other substrate manufacturing control devices that are unable to control the chambers automatically and in real-time.

In some embodiments, computation models of a digital twin device comprise one or more virtual models of a physical twin chamber. A virtual model may be configured to model, for example, fluid dynamics, direct simulation Monte Carlo (DSMC), electromagnetic (EM) field solvers, optical modeling tools, or direct computation of mathematical equations representing the physical twin chamber. The virtual model may be used to perform real-time monitoring and analysis of the state of the physical twin chamber.

Furthermore, virtual models implemented in a digital twin device may be configured to model attributes of the substrate that is being processed or was processed in the physical twin chamber itself (or the substrates themselves). For instance, one of the virtual models may model attributes of the substrate's physical and mechanical properties, due to process data detected during processing and/or types of processing performed on the substrate by components of a physical twin chamber, and the like. The information provided from measurements taken from the substrate and provided to the digital twin device may include information about one or more film layers formed on the substrate, the residue on the substrate, and the like.

The computational models implemented in the digital twin device may also include models of electrical characteristics, models of mechanical characteristics, models of fluid delivery characteristics, and/or models of vacuum environment characteristics. The computations models may be configured to capture corresponding physical and chemical actions reported by one or more sensors within one or more of the subsystems of the physical twin chamber. The corresponding and chemical computational models may include heat transfer, transmission of electricity, electrical pulses, EM radiation, chemical reactions, material phase, erosion, and/or wear due to physical contact.

The digital twin device may be configured to model the characteristics and the processes of the physical twin chamber using models that may include a lumped parameter system modeling networking tools, network models for solving systems of electrical circuits, and/or derivatives of network models.

### Example Digital-Physical Twin Pair Configuration

The drawing figures and all of the descriptions and claims in this disclosure are intended to present, disclose, and claim a technical system and technical methods in which specially programmed computers, using a special-purpose distributed computer system design, execute functions that have not been available before to provide a practical application of computing technology to the problem of machine learning model development, validation, and deployment. In this manner, the disclosure presents a technical solution to a technical problem, and any interpretation of the disclosure or claims to cover any judicial exception to patent eligibility, such as an abstract idea, mental process, method of organizing human activity, or mathematical algorithm, has no support in this disclosure and is erroneous.

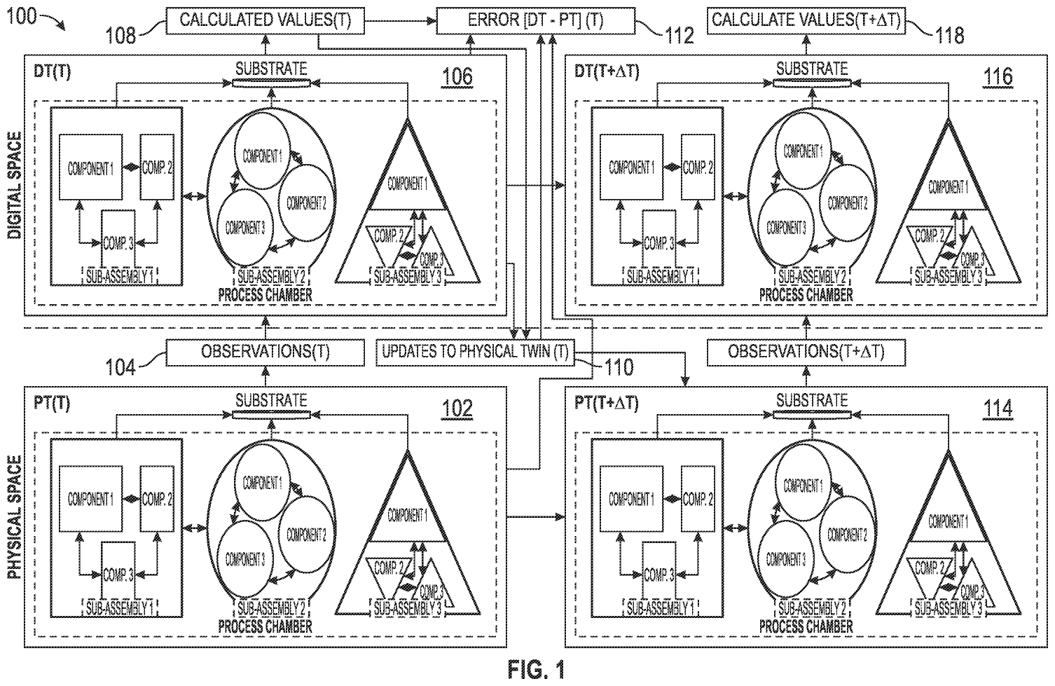

FIG. 1 is an example graphical representation 100 of a digital-physical twin pair according to some embodiments of the present principles. In FIG. 1, a physical twin (PT) 102 operates in a physical space, while a digital twin (DT) 106 operates in a digital space. As time passes (i.e., t+Δt), physical twin 102 is shown as a physical twin 114, while digital twin 106 is shown as a digital twin 116.

Physical twin 102/114 may include one or more sub-assemblies (not shown). Each sub-assembly may have its components (including, for example, a Component 1, a Component 2, a Component 3, and the like). In one example, Component 1 of the physical twin 102/114 may include an electrostatic chuck (ESC) that is disposed within an ESC sub-assembly, which, for example, is configured to control the temperature, electrostatic force, and substrate bias applied to a substrate disposed on a surface of the ESC during processing. In this example, other sub-assemblies can include a radio frequency (RF) delivery sub-assembly, which is configured to efficiently provide RF power to an electrode disposed within the physical twin, or a substrate positioning or motion control sub-assembly which is configured to provide adjust and control the position of the substrate disposed within the physical twin.

Similarly, digital twin 106/116 may include one or more sub-assemblies (not shown), and each sub-assembly may have its components (including, for example, a Component 1, a Component 2, a Component 3, and the like). In one example, Component 1 of the digital twin 106/116 may include a thermal model of the ESC that is disposed within a substrate support assembly model, which, for example, is configured to model and collect virtual data regarding the temperature of a substrate disposed on a surface of the ESC during processing.

At time t, the states of the components and the processes of physical twin 102 may be communicated to digital twin 106 as observations 104 (i.e., input). Based on observations 104, digital twin 106 calculates values (108) which may include updates 110 (i.e., output) that are transmitted, or otherwise communicated, to physical twin 114 in time t+Δt.

Calculated values 108 may also include errors 112 (i.e., additional output) between the performance of digital twin 106 and physical twin 102 at time t. Errors 112 may indicate, for example, that the actual performance of physical twin 102 is different from the expected performance of physical twin 102 determined based on the data provided to the digital twin 106. Errors 112 may be also determined based on both calculated values 108 and updates 110 determined at time t. Error information 112 may be monitored, reported, and otherwise processed to improve the performance of physical twin 114 at t+Δt.

At time t+Δt, the process is repeated, but this time for physical twin 114 and digital twin 116. At time t+Δt, the states of the components and the processes of physical twin 102 may be communicated to digital twin 116 as observations (i.e., input). Based on the observations, digital twin 116 calculates values 118 (i.e., output), which may include updates (not shown in FIG. 1) that can be transmitted, or otherwise communicated, to a physical twin (not shown in FIG. 1) at time t+Δt+Δt. The process within the physical twin can be updated by the use of a physical twin controller within the corresponding components.

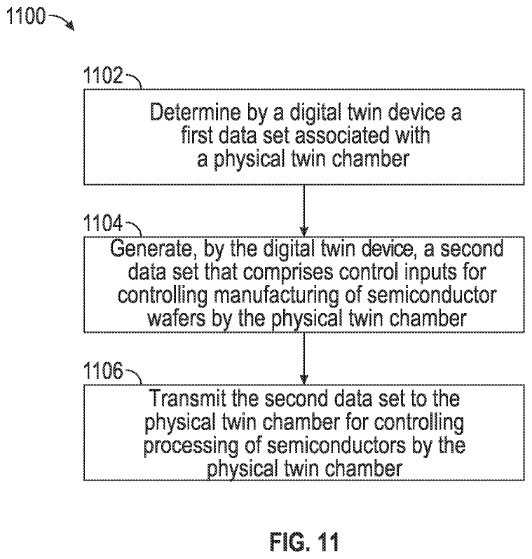

FIG. 11 is an example process 1100 executed by a digital twin device of a digital-physical twin pair according to some embodiments of the present principles. The process is a method performed by a digital twin device and it is for controlling a physical twin chamber that is processing substrates. The digital twin device captures and models the characteristics and processes of the physical twin chamber and generates control inputs for controlling the physical twin chamber. The digital twin device models the characteristics and the processes of the physical twin chamber using several models that include, for example, a lumped parameter system modeling networking tools, network models for solving systems of electrical circuits, derivatives of network models, and the like.

The digital twin device comprises one or more computational models, components, and subsystems for modeling the characteristics and processes and generating control inputs. The computations models may be configured to capture corresponding physical and chemical data reported by the subsystems. The corresponding data may include, for example, heat transfer, transmission of electricity, electrical pulses, EM radiation, chemical reactions, material phase, erosion, and/or wear due to physical contact type data.

The computation models of the digital twin device may also include a virtual model of the physical twin chamber. Using at least the virtual model, the digital twin device performs real-time monitoring and controlling of the physical twin chamber. The digital twin device monitors and controls the physical twin chamber by executing one or more fast-running network models and empirically built relational data models.

As discussed above, the virtual model may be configured to model, for example, fluid dynamics, direct Monte Carlo (DSMC) simulation, magneto-hydrodynamic particle-in-cell simulation, EM solvers, optical modeling tools, and/or direct computation of mathematical equations representing the physical twin chamber. The computational models of the digital twin device may include, for example, models of electrical characteristics, models of mechanical characteristics, models of fluid delivery, and/or models of vacuum environment characteristics.

In some embodiments, a virtual model is constructed empirically from observed and measured data from the physical twin chamber. The virtual model may be configured to evaluate the performance of the physical twin chamber relative to its expected or historical performance as established by prior data.

The virtual model may also be configured to compare the performance characteristics of the digital twin device and the physical twin chamber to evaluate the accuracy of the virtual model to the real-world results of the physical twin chamber. Furthermore, the virtual model may be configured to evaluate data provided from both the physical twin chamber and the digital twin device to create actionable insights to improve the performance of the physical twin chamber.

The components and models may be implemented, for example, in one or more AI-based applications that are described later.

Referring again to FIG. 11, at block 1102, a digital twin device determines the first data set associated with a physical twin chamber. The first date set may be determined using various approaches. For example, the first data set may be received by the digital twin device via one or more communications interfaces.

In this context, the first data set may include the input to, for example, a neural network implementing an AI application or other AI-based approach, as described later. The input data may be provided to the AI application to initiate, for example, initial parameters and their corresponding weights used in the AI neural network.

In some implementations, the first data set (e.g., the input to the AI application) includes, for example, direct measurement of physical processes collected and reported by probes and sensors implemented in a physical twin chamber. The first data set may also include data collected and reported by internal virtual sensors of the digital twin device. For instance, the first data set may include values of the temperature-related parameters provided by the probes and sensors of the physical chamber, or by the related processes, and other parameter values that may be used to determine the current temperature of the physical chamber concerning various types of substrate processing performed within the chamber.

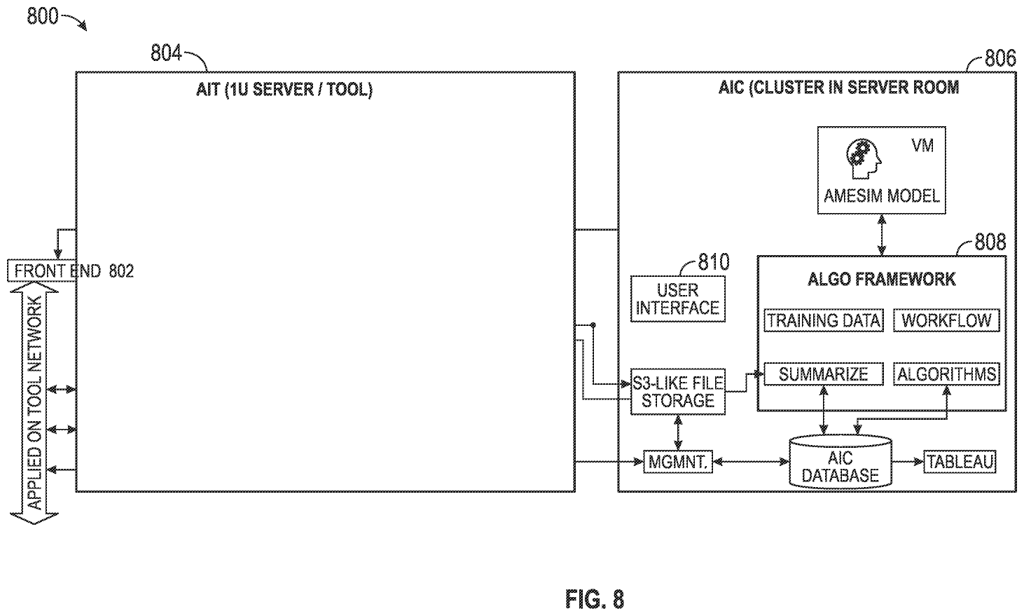

The first data set may be received by the digital twin device from, for example, sensors and probes, and/or via one or more communications interfaces. The communications interfaces are usually devices that are configured to facilitate communications between a digital twin device and a physical twin chamber (e.g., sensors and probes). In some configurations, the communications interfaces may facilitate communications between a plurality of digital twin devices and the corresponding plurality of twin chambers. Various configurations are described in FIG. 8-10.

At block 1104, the digital twin device automatically generates the second data set that comprises analysis information for the physical twin chamber. The second data set may include, for example, the output generated by an AI-based application. The output may include, for example, control commands, control parameters, or instructions that may be used by operators to fine-tune, or adjust, the control parameters of the physical twin chambers.

In this context, the second data set (e.g., the output generated and provided by the AI application) may include updates (element 110 shown in FIG. 1) to the physical twin and may be generated by the digital twin based on, for example, calculated values (element 108 shown in FIG. 1), error information (element 112 shown in FIG. 1), and the like. The updates may be communicated to the corresponding physical twin chamber (element 114 shown in FIG. 1) to fine-tune, or adjust, the parameters of the physical chamber. For instance, if the first data set includes values of the temperature-related parameters provided by the physical chamber, or the related processes, and other temperature-related parameter values, then the second data set may include the control parameters or instructions that may be used by the operators or controller to fine-tune the temperature related parameters of the physical chamber until the error between the temperatures reported by the physical chamber and derived by the corresponding digital twin is negligible.

The second data set may be automatically generated by the digital twin device based on, at least in part, the first data set, and by executing, for example, the AI-based computational models, components, and subsystems of the digital twin device on the first data set.

At block 1106, the digital twin device transmits the second data set to the physical twin chamber to allow the operators to control and fine-tune the processing of substrates by the physical twin chamber. In one example, the first data set received by the digital twin device (e.g., the AI-based application) includes values of the temperature-related parameters provided by the physical chamber, or the related processes. Furthermore, the second data set generated by the AI-based application includes the control parameters or instructions to be used by the operators to fine-tune the temperature-related parameters of the physical chamber. Then upon receiving the second data set, the operators may use the received control parameters/instructions to fine-tune the temperature-related parameters of the physical chamber until the error between the temperature reported by the physical chamber and the temperature determined by the corresponding digital twin is negligible. This may include, for example, adjusting the temperature set point to account for the emissivity change and the like.

In some embodiments, the digital twin generates the second data set and transmits the second data set to the physical twin contemporaneously while receiving the first data set from the physical twin chamber. This aspect of the approach was referred to and described above as real-time processing.

### Example Thermal Digital-Physical Twin Pair Configuration

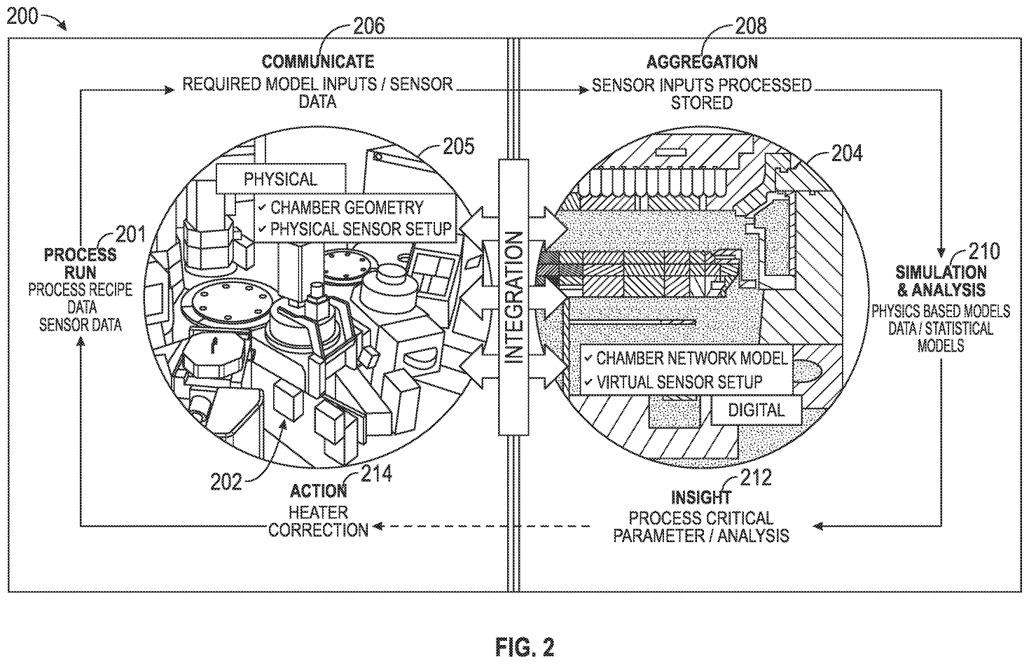

FIG. 2 is an example graphical representation 200 of one type of digital-physical twin pair that includes a thermal digital-physical twin pair according to some embodiments of the present principles. In FIG. 2, a physical twin chamber 202 is integrated with a digital twin device 204. However, in comparison with FIG. 1 which depicts a general application of the pair, the twin pair of FIG. 2 is configured to monitor and control thermal processes performed and occurring in physical twin chamber 202 positioned within a physical twin system 205.

The thermal processes executed by physical twin chamber 202 are quite complex. For example, process 201 may include complicated thermal processing recipes, determining the chamber process conditions, collecting the sensor data, and the like.

Data collected and obtained by process 201 may include required model inputs and sensor data. The data may be communicated (206) to the digital twin device 204. The data may be transformed to, for example, the model input/sensor formats before the data is provided to digital twin device 204.

The received data are aggregated (i.e., aggregation process 208) and used to perform a simulation and analysis 210. The simulation/analysis may include executing the received data using various physics-based models, data/statistical processing, and the like. In one example, the models used during the analysis can include models constructed in AMESIM, MATLAB, or other similar software tools for model building and analysis.

Output from the simulation and the analysis may be used to generate a so-called insight 212. Insight may include process critical parameters, emissivity characteristics, thermal uniformity data, process and sensor drift information, substrate digital twin data, and the like.

Insight 212 may be transmitted, or otherwise provided, to physical twin chamber 202 to determine, for example, various actions 214. The actions may include, for example, heater offset corrections, zone ratio tuning, SH conditioning, and the like. In some implementations, a heated pedestal (wafer substrate susceptor) is used. It may have inner and outer zones, and the ratio of the power distribution to each zone can be adjusted. Actions 214 are examples of corrective actions performed concerning physical twin chamber 202 and the processes performed by physical twin chamber 202.

As actions 214 are performed concerning the processes performed by physical twin chamber 202, the execution of the processes continues and new process data 201 are collected and then communicated 206 to digital twin device 204.

The process described above is referred to as a closed-loop process or a feedback process. It usually includes collecting the process-run data at physical twin chamber 202, communicating the data to digital twin device 204, performing simulation/analysis 210 of the data, generating insight 212, and determining actions 214.

The digital twin device may determine the insight automatically and transmit the insight to the physical twin chamber in real time. The automation of the process and execution of the process in real-time provides many benefits in terms of efficiency and accuracy of controlling and managing the physical twin chamber.

The speed with which the process corrections are made by the use of the digital-physical twin pair allows for lowering the likelihood of misprocessing one or more substrates. That in turn allows improving the physical device yield during the substrate processing while reducing substrate scrap.

### Example Digital-Physical Twins Chamber-to-Substrate Configuration

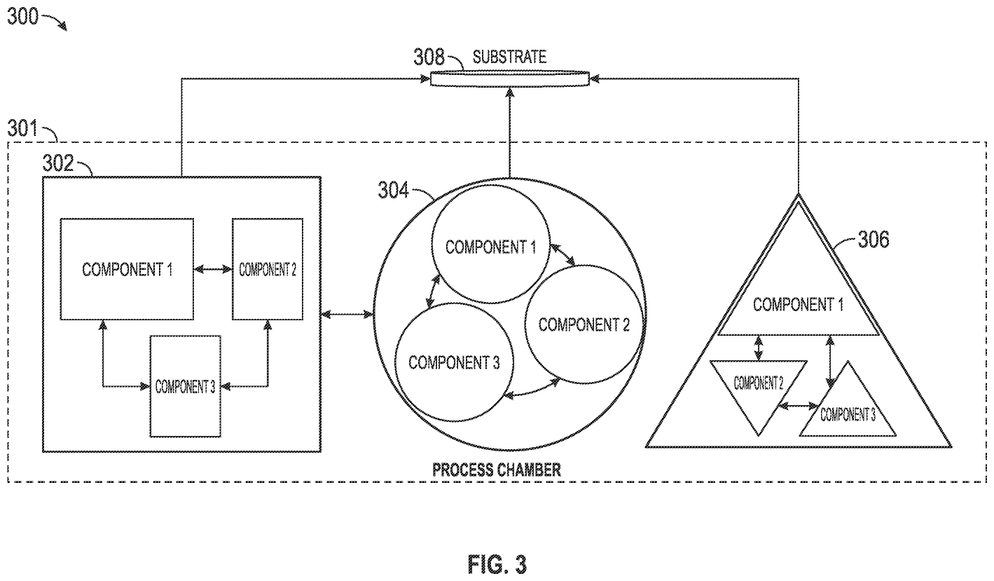

FIG. 3 is an example coupled system 300 of a physical and digital twin for processing substrates according to some embodiments of the present principles. FIG. 3 is a detailed depiction of the configuration that is also depicted in FIG. 1. The difference is that FIG. 3 depicts how the processes 302, 304, and 306 of a physical twin chamber 301 interact with each other during processing a substrate, which in this case is substrate 308.

In FIG. 3, physical twin (PT) chamber 301 operates in a physical space. Physical twin chamber 301 may include one or more process chambers 302, 304, 306, and the like. Each chamber may have its components, including, for example, a Component 1, a Component 2, a Component 3, and the like.

FIG. 3 also depicts that the components communicate with each other during the processing of the substrate. Furthermore, the components execute various processes on substrate 308. The states of the processes, the states of the assemblies, and the information exchanged between the components may be intercepted, monitored, and used by a digital twin device (not shown in FIG. 3) to determine control inputs to physical twin chamber 301.

For example, at time t, the states of the components and the processes of physical twin chamber 301 may be communicated to a digital twin (not shown in FIG. 3) as observations (not shown in FIG. 3). Based on the observations, the digital twin device may calculate data (not shown in FIG. 3) relating to the expected state of components and/or process variables at time t, as was described before about FIG. 1. The values may include updates (not shown in FIG. 3) that may be transmitted, or otherwise communicated, to physical twin chamber 301 for subsequent use by the control system(s) within physical twin chamber 301.

The calculated values may also include detected errors (not shown in FIG. 3) between the performance of the digital twin device (not shown in FIG. 3) and physical twin chamber 301 at time t. The errors may indicate, for example, whether the actual performance of physical twin 301 is different from the expected performance determined based on at least some data provided to the digital twin device at time t.

The error information may be also determined based on both the calculated values and the updates determined at time t. The error information may be monitored, reported, and otherwise processed, by one or more controllers disposed within one or more of the sub-assemblies within the physical twin chamber, to improve the performance of physical twin chamber 301 at, for example, some later time.

### Example Digital-Physical Twins for Substrate Processing Configuration

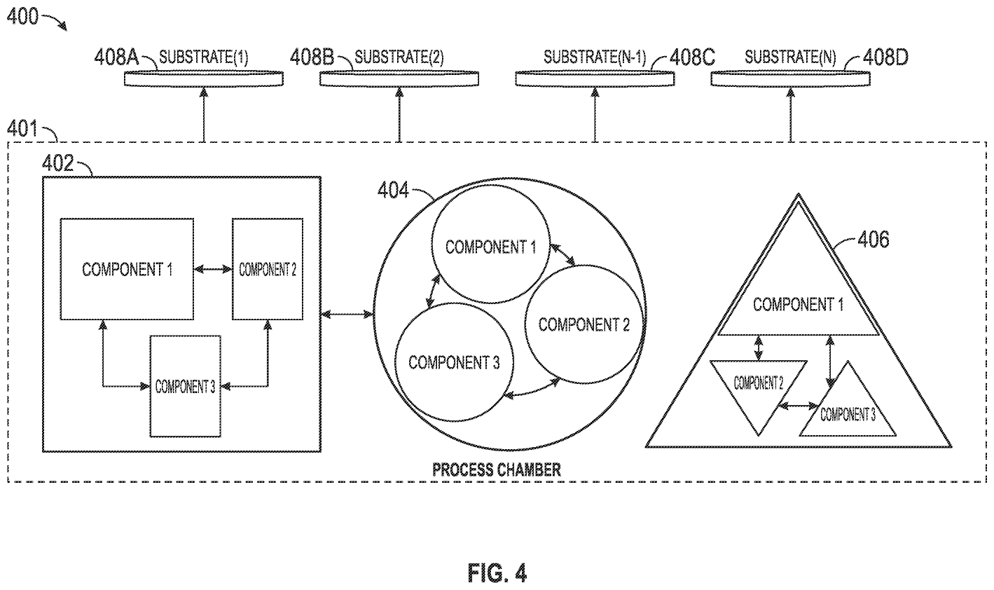

FIG. 4 is an example coupled system 400 of physical and digital twins for multiple processes performed in a time sequence according to some embodiments of the present principles. FIG. 4 depicts an arrangement that is more complex than the arrangement depicted in FIG. 3. The difference is that FIG. 4 depicts a substrate manufacturing process sequence executed by various processes of a physical twin chamber 401 at a time t sequence, including the processing of substrate(t₁), substrate(t₂), . . . substrate(t_{N-1}), substrate(t_{N}), and so forth, while FIG. 3 relates to processes performed on a substrate at time to. The notation substrate(t₁), substrate(t₂), . . . substrate(t_{N-1}), substrate(t_{N}) may be abbreviated to substrate(1) 408A, substrate(2) 408B, . . . substrate(N−1) 408C, and substrate(N) 408D, respectively.

FIG. 4 also shows how the processes of a physical twin 401 interact with each other during the process of manufacturing substrates, including substrate(1), substrate(2), . . . substrate(N−1), and substrate(N).

In FIG. 4, physical twin (PT) 401 operates in a physical space. Physical twin 401 may include one or more processes 402, 404, 406, and the like. Each process may have its components, including, for example, a Component 1, a Component 2, a Component 3, and the like.

In one example, Component 1 of process 402 of physical twin 401 may capture the physical or mechanical properties of a portion of the substrate in the substrate processing sequence. In this example, Component 1 can include film stress data, film composition data, or reflectance data collected on the substrate by one or more sensors. In this example, the substrate is processed according to the substrate processing sequence, and thus the physical and digital twin pairs are configured to adjust and control one or more aspects of one or more processing recipes within each substrate processing activity/step within the processing sequence.

FIG. 4 also depicts that the processes communicate with each other during the process of manufacturing the substrate. Furthermore, the processes execute various processes on the substrate at t, including substrate(1), substrate(2), . . . substrate(N−1), and substrate(N). Other configurations may include additional processing sequences than those depicted in FIG. 4.

The states of the processes, the states of the assemblies, and the information exchanged between the components may be intercepted, monitored, and used by the digital twin device (not shown in FIG. 4) to determine control inputs for physical twin 401.

For example, at time t, the state of the components and the processes of physical twin 401 may be communicated to a digital twin (not shown in FIG. 4) as observations (not shown in FIG. 4). Based on the observations, the digital twin device may calculate values (not shown in FIG. 4) that were described in FIG. 1. The values may include updates (not shown in FIG. 4) that may be transmitted, or otherwise communicated, to physical twin 401. The updates may be used as described in FIG. 1 and FIG. 3.

The physical-digital twin is running in parallel with the chamber physical-digital twins so that the additional information gained by the FIG. 4 physical-digital twin can be used to correct problems not detected by the individual physical-digital twins.

### Example Digital-Physical Twins for Multi-Chamber System-to-Substrate Configuration

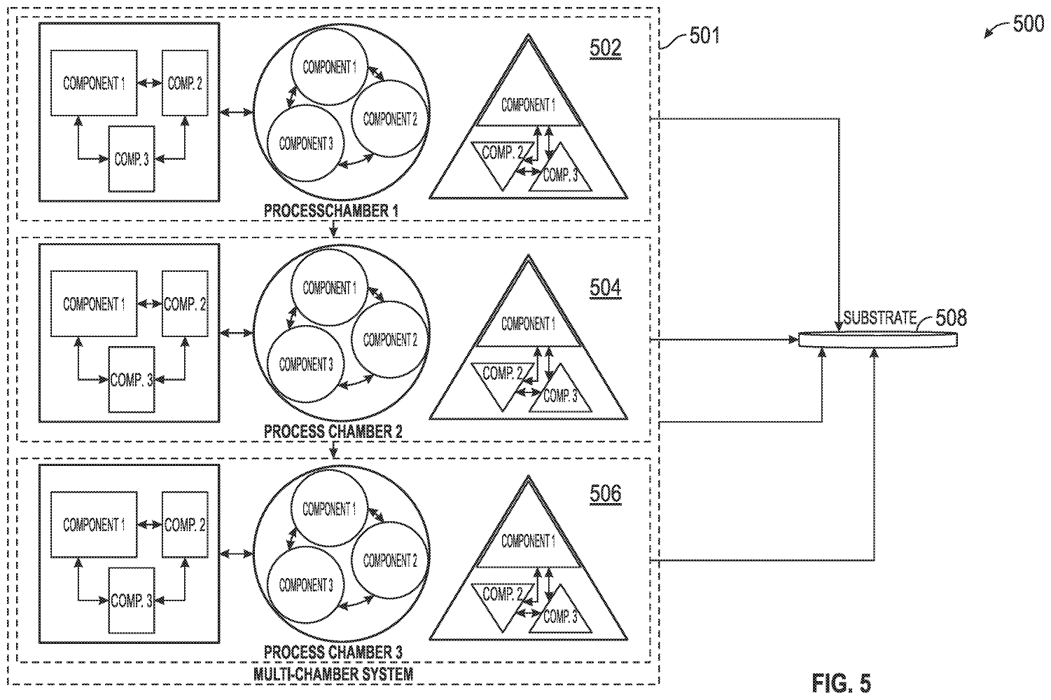

FIG. 5 is an example coupled system 500 of physical and digital twins for multiple processes for processing substrates according to some embodiments of the present principles. FIG. 5 depicts a configuration in which multiple process chambers of a multi-chamber system 501 are executed to process a substrate, i.e., substrate 508. The multiple process chambers of multi-chamber system 501 shown in FIG. 5 include a first process chamber 502, a second process chamber 504, and a third process chamber 506.

In one example, the first process chamber 502 includes a pre-clean chamber, the second process chamber 504 includes a PVD chamber that is configured to deposit a first metal layer on the substrate, and the third process chamber 506 which includes a CVD chamber or a thermal processing chamber and that is configured to either deposit a second metal layer on the first metal layer or anneal the first metal layer disposed within a cluster tool (e.g., Endura® available from Applied Materials Inc.). Other configurations may include additional process chambers or fewer chambers than the ones depicted in FIG. 5.

According to FIG. 5, each of process chambers 502/504/506 may have or be coupled to, its own corresponding digital twin device (not shown in FIG. 5). Alternatively two or more chambers may be coupled to a digital twin device (not shown in FIG. 5).

A digital twin device utilized in coupled system 500 may be used to monitor and alter aspects of a processing sequence performed on substrate 508 based on the use of the physical-digital twin pair that is monitoring and controlling multi-chamber system 501 (i.e., a physical twin).

FIG. 5 also shows that process chambers 502/504/506 interact with each other during the process of manufacturing the substrate (including substrate 508).

In FIG. 5, multi-chamber system 501 operates in a physical space, and each process chamber (of process chambers 502/504/506) may include its own one or more sub-assemblies (not shown in FIG. 5). Each sub-assembly may have its components (including, for example, a Component 1, a Component 2, a Component 3, and the like). In one example, Component 1 of the physical twin associated with the multi-chamber system 501 may include hardware components within process chamber 502, such as a Vacuum Chuck. (In some other examples, an Electric-Static Chuck (ESC) may be included in the process chamber 502.) In this example, component 1 can include a chuck that is included in process chamber 504, and component 1 can include a chuck that is included in process chamber 506. In this example, the physical and digital twin pair is configured to adjust and control one or more process variables utilized during the performance of a processing sequence performed within the multi-chamber system 501 to control and improve the process results for all of the substrates processed in the substrate processing sequence.

FIG. 5 also depicts that the process chambers 502/504/506 communicate with each other during substrate manufacturing. Furthermore, each process chamber and the corresponding components communicate with each other during the process of manufacturing the substrate. Moreover, the process chambers and the corresponding sub-assemblies execute various processes on the substrate such as substrate 508.

For each process chamber (of process chambers 502/504/506), the states of the chamber's processes, the states of the assemblies, and the information exchanged between the chamber's components, and the chamber's sub-assemblies may be intercepted, monitored, and used by the chamber's corresponding digital twin device (not shown in FIG. 5) to determine control inputs for the corresponding process chamber.

For example, at time t, the states of the components and the processes of process chamber 502 may be communicated to the chamber's corresponding digital twin (not shown in FIG. 5) as observations (not shown in FIG. 5). Based on the observations, the digital twin device may calculate values (not shown in FIG. 5) that were described in FIG. 1. The values may include updates (not shown in FIG. 5) that may be transmitted, or otherwise communicated, to process chamber 502. The updates may be used as described in FIG. 1 and FIG. 3 to control, for example, process chamber 502.

In some embodiments, additional digital twin devices (not shown in FIG. 5) may be implemented to control and monitor, for example, interactions between process chambers 502/504/506, and/or to control and monitor, for example, the overall performance of multi-chamber system 501. Thus, a physical and digital twin pair can be utilized to separately control aspects of a process running within a process chamber, such as a process chamber 502, 504, or 506, and a separate physical and digital twin pair can also be used to control and improve the process sequence performed in the multi-chamber system 501 that includes the process chambers 502, 504 and 506.

The above method may be executed in parallel by each of process chambers 502/504/506, and the updates, along with corresponding control inputs, may be provided contemporaneously to the corresponding process chambers 502/504/506.

The physical-digital twin is running in parallel with the chamber physical-digital twins so that the additional information gained by the FIG. 5 physical-digital twin can be used to correct problems not detected by the individual physical-digital twins.

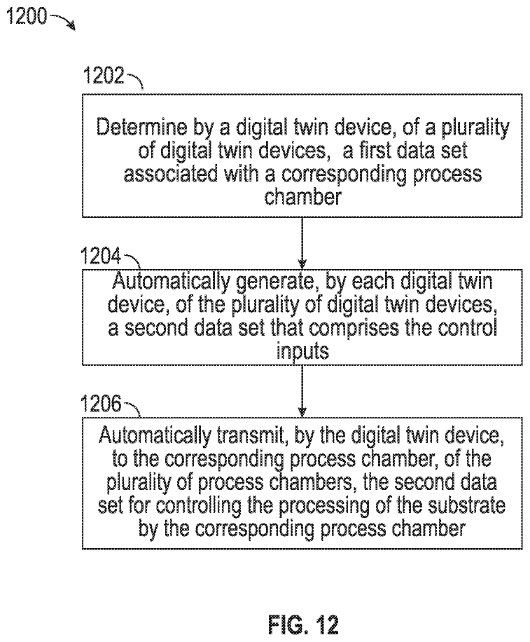

FIG. 12 is an example process executed by a digital twin device of a physical and digital twin for multiple processes for processing substrates according to some embodiments of the present principles. Digital twin devices were described, for example, in FIG. 11.

At block 1202, each digital twin device, of a plurality of digital twin devices, determines the first data set associated with a corresponding process chamber of a plurality of process chambers. The first data set may be determined using various approaches, including receiving the first data set via one or more communications interfaces of a plurality of communications interfaces. For example, the first data set may be received by the digital twin device via one or more communications interfaces.

In this context, the first data set may include the input to, for example, a neural network implementing an AI application or other AI-based approach, as described later. The input data may be provided to the AI application to initiate, for example, initial parameters and their corresponding weights used in the AI neural network.

In some implementations, the first data set (e.g., the input to the AI application) includes, for example, direct measurement of physical processes collected and reported by probes and sensors implemented in a physical twin chamber. The first data set may also include data collected and reported by internal virtual sensors of the digital twin device. For instance, the first data set may include values of the temperature-related parameters provided by the probes and sensors of the physical chamber, or by the related processes, and other parameter values that may be used to determine the current temperature of the physical chamber concerning various types of substrate processing performed within the chamber.

The first data set may be received by the digital twin device from, for example, sensors and probes, and/or via one or more communications interfaces. The communications interfaces are usually devices that are configured to facilitate communications between a digital twin device and a physical twin chamber (e.g., sensors and probes). In some configurations, the communications interfaces may facilitate communications between a plurality of digital twin devices and the corresponding plurality of twin chambers. Various configurations are described in FIG. 8-10.

The digital twin devices, of the plurality of digital twin devices, control and monitor the interactions between the process chambers of the plurality of process chambers. Furthermore, the digital twin devices control and monitor a plurality of tasks that are executed by the process chambers while the process chambers process the substrate.

In some implementations, each digital twin device is associated with the corresponding process chamber and comprises one or more computational models, components, and subsystems to model the characteristics and processes and generate the control inputs. The computational models, components, and subsystems are also configured to generate the control inputs.

The computation models of each digital twin device comprise one or more virtual models of the corresponding process chamber of the plurality of process chambers.

In some embodiments, a virtual model of a digital twin device evaluates the performance of the corresponding process chamber, of the plurality of process chambers, relative to its expected or historical performance as established by prior data. The virtual model may also be configured to compare the performance characteristics of the digital twin device and the corresponding process chamber, of the plurality of process chambers, to evaluate the accuracy of the virtual model to the real-world results of the corresponding process chamber. Furthermore, the virtual model may be configured to use evaluation of the data from both the corresponding process chamber and the digital twin device to create actionable insights to improve the performance of the corresponding process chamber.

In some embodiments, process chambers interact with each other while the process chambers manufacture substrate. Furthermore, the process chambers execute a plurality of tasks while manufacturing the substrate.

The first data set may include direct measurements of physical processes collected and reported by probes and sensors implemented in the corresponding process chamber and data collected and reported by internal sensors of the digital twin device.

The communications interfaces may be configured to facilitate communications between the digital twin devices and the process chambers.

At block 1204, each digital twin device, of a plurality of digital twin devices, automatically generates the second data set that comprises control inputs. The second data set is automatically generated by the digital twin device based on, at least in part, the first data set, and by executing one or more computational models, components, and subsystems of the digital twin device.

The second data set may include, for example, the output generated by an AI-based application of the digital twin device. The output may include, for example, control commands, control parameters, or instructions that may be used by operators of physical chambers, or by the physical chambers themselves, to fine-tune, or adjust, the control parameters of the physical chambers.

In this context, the second data set (e.g., the output generated and provided by the AI application) may include updates (element 110 shown in FIG. 1) to the physical twin and may be generated by the digital twin based on, for example, calculated values (element 108 shown in FIG. 1), error information (element 112 shown in FIG. 1), and the like. The updates may be communicated to the corresponding physical twin chamber (element 114 shown in FIG. 1) to fine-tune, or adjust, the parameters of the physical chamber. For instance, if the first data set includes values of the temperature-related parameters provided by the physical chamber, or the related processes, and other temperature-related parameter values, then the second data set may include the control parameters or instructions that may be used by the operators to fine-tune the temperature related parameters of the physical chamber until the error between the temperatures reported by the physical chamber and derived by the corresponding digital twin is insignificant.

Each digital twin device automatically generates the second data set contemporaneously by receiving the first data set from the corresponding process chamber.

At bock 1206, each digital twin device automatically transmits the second data set to the corresponding process chamber for controlling the manufacturing of substrates by the corresponding process chamber. For example, if the first data set received by the digital twin device (e.g., the AI-based application) includes values of the temperature-related parameters provided by the physical chamber, or the related processes, then the second data set generated by the AI-based application includes the control parameters or instructions to be used by the operators to fine-tune the temperature-related parameters of the physical chamber. Upon receiving the second data set, the operators may use the received control parameters/instructions to fine-tune the temperature-related parameters of the physical chamber until the error between the temperature reported by the physical chamber and the temperature determined by the corresponding digital twin is negligible. This may include, for example, adjusting the temperature set point to account for the emissivity change and the like.

### Example Digital-Physical Twins for Multi-Chamber System-to-Substrates Configuration

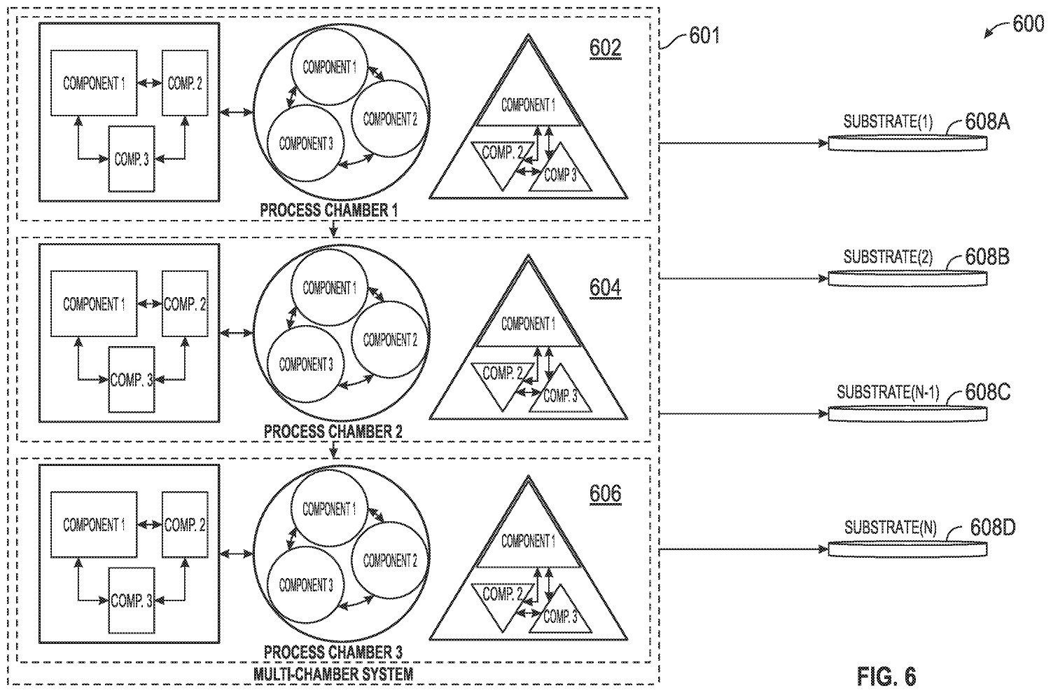

FIG. 6 is an example of a coupled system 600 of multiple physical and digital twins for multiple processes performed in a time sequence according to some embodiments of the present principles. FIG. 6 depicts a multi-chamber configuration which depicts a substrate manufacturing process sequence executed by various processes of a physical twin chamber 601 at a time t sequence, including the processing of substrate(t₁), substrate(t₂), . . . substrate(t_{N-1}), substrate(t_{N}), and so forth, while FIG. 3 relates to processes performed on a substrate at time to. The notation substrate(t₁), substrate(t₂), substrate(t_{N-1}), substrate(t_{N}) may be abbreviated to substrate(1) 608A, substrate(2) 608B, . . . substrate(N−1) 608C, and substrate(N) 608D, respectively. The processing may be performed, for example, sequentially, or in parallel. Furthermore, each digital twin (not shown in FIG. 6) models the corresponding processes of the chambers and models the characteristics and properties of the substrate.

The multiple chamber processes of multi-cluster tool system 601 shown in FIG. 6 include a first cluster tool 602, a second cluster tool 604, and a third cluster tool 606. Each of the cluster tools 602/604/606 can be itself a cluster tool (e.g., Endura®, Producer®, Centura®) that is available from Applied Materials Inc., of Santa Clara, California. Other configurations may include additional chamber processes or fewer chambers than those depicted in FIG. 6.

In one example, the first cluster tool 602 includes a cluster tool that includes one or more dielectric layer deposition chambers (e.g., CVD chambers) that are used to form a dielectric layer (e.g., TEOS layer, high-k layer, etc.) on a surface of a substrate. The second cluster tool 604 may include a cluster tool having one or more etching chambers that are used to etch features in the deposited dielectric layer formed on the surface of a substrate. The third cluster tool 606 may include a cluster tool that includes one or more metal deposition chambers (e.g., PVD chambers) that are used to deposit a metal layer within the features formed in the deposited dielectric layer formed on the surface of a substrate, which are all disposed within one or more semiconductor device fabrication sites.

The processes interact with each other during the process of manufacturing substrate along time t (e.g., substrate(1), substrate(2), . . . substrate(N−1), and substrate(N)).

According to FIG. 6, each of the cluster tools 602/604/606 may have, or be coupled to, its own corresponding digital twin device or devices (not shown in FIG. 6).

In FIG. 6, cluster tool system 601/604/606 operates in a physical space, and each cluster tool 602/604/606 may include its sub-assemblies (not shown in FIG. 6). Each sub-assembly may have its components, including, for example, a Component 1, a Component 2, a Component 3, and the like. Each of the processes, each of the sub-assemblies, and each of the components may be modeled by a separate digital twin. Alternatively, groups of the processes, sub-assemblies, and/or components may be modeled by individual digital twins.

In one example, Component 1 of the physical twin associated with first cluster tool 602 may include hardware components within a process chamber, such as a CVD dielectric deposition chamber that is disposed of within the first cluster tool 602. Also in this example, Component 1 of the second cluster tool 604 may include a PVD deposition chamber and the like.

The physical and digital twin pair can be configured to adjust and control one or more process variables utilized during the performance of a processing sequence performed within the cluster tool system 601 to control and improve the process results for the substrate.

FIG. 6 also depicts that the cluster tool processes, including chamber processes performed in cluster tools 602, 604, and 606, and their corresponding sub-assemblies and components may communicate with each other during the process of manufacturing the substrate along the time t (including substrate(1), substrate(2), . . . substrate(N−1), and substrate(N)).

Furthermore, each chamber process (including chamber processes 602/604/606) communicates with each other during the process of manufacturing the substrate. Moreover, the processes performed in each of the cluster tools and the corresponding sub-assemblies within each cluster tool execute various processes on the substrate along the timeline (e.g., substrate(1), substrate(2), . . . substrate(N−1), and substrate(N)).

Each digital twin device (not shown in FIG. 6) may intercept/receive and monitor the states of the corresponding cluster tool's processes, the states of the assemblies, the information exchanged between the corresponding cluster tool's components and the cluster tool's sub-assemblies, and the characteristics of the substrate that the processes performed in the cluster tool at the given time. The information may be used by the digital twin device (not shown in FIG. 6) to determine control inputs for the corresponding chamber processes within one or more of the chambers within one or more of the cluster tools.

For example, at time t, various types of information may be communicated to a corresponding digital twin device (not shown in FIG. 6). The information may include observations (not shown in FIG. 6), the states of the components, and the processes of the first cluster tool 602 as well as the states of the assemblies, the information exchanged between the cluster tool's components and the cluster tool's sub-assemblies, and the characteristics of the substrate that the chamber processes performed in the cluster tool have generated. Based on the information, the digital twin device (not shown in FIG. 6) may calculate values that were described in FIG. 1. The values may include updates (not shown in FIG. 6) that may be transmitted, or otherwise communicated, to the processes performed in the cluster tools 602, 604, and 606. The updates may be used as described in FIG. 1 and FIG. 3 to control the corresponding processes.

The above method may be executed in parallel, sequentially, or parallel and sequentially for each of cluster tool processes 602/604/606, and the updates, along with corresponding control inputs, may be provided to the corresponding processes performed in the cluster tools 602, 604, and 606.

The physical-digital twin may be running in parallel with the chamber physical-digital twins so that the additional information gained by the FIG. 6 physical-digital twin can be used to correct problems not detected by the individual physical-digital twins.

In some embodiments, additional digital twin devices (not shown in FIG. 6) may be implemented to control and monitor, for example, interactions between chamber processes performed within the cluster tools 602, 604, and 606, and/or to control and monitor, for example, the overall performance of cluster tool system 601. Additional twins may be also implemented to model the characteristics and properties of the substrates. Those models may cooperate with other models of digital twins.

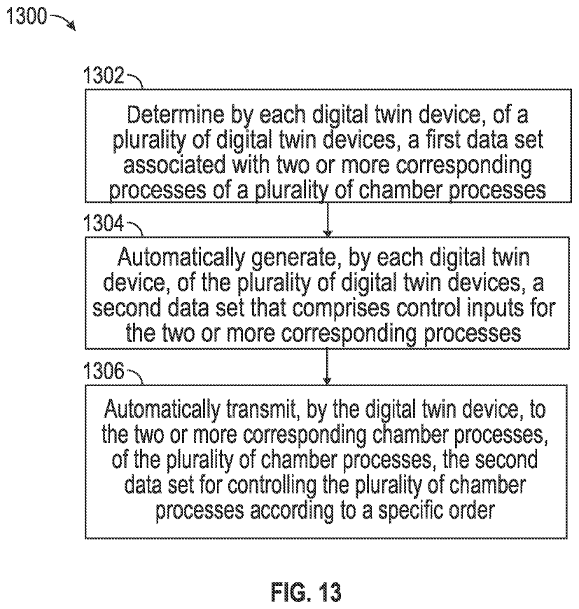

FIG. 13 is an example process executed by a digital twin device of a physical and digital twin for multiple processes performed in a time sequence according to some embodiments of the present principles. More specifically, FIG. 13 depicts a method for controlling a cluster tool system for manufacturing a substrate along the timeline.

At block 1302, each digital twin device, of a plurality of digital twin devices, determines the first data set associated with a physical twin chamber. The first date set may be determined using various approaches. For example, the first data set may be received by the digital twin device via one or more communications interfaces.

In this context, the first data set may include the input to, for example, a neural network implementing an AI application or other AI-based approach, as described later. The input data may be provided to the AI application to initiate, for example, initial parameters and their corresponding weights used in the AI neural network.

In some implementations, the first data set (e.g., the input to the AI application) includes, for example, direct measurement of physical processes collected and reported by probes and sensors implemented in a physical twin chamber. The first data set may also include data collected and reported by internal virtual sensors of the digital twin device. For instance, the first data set may include values of the temperature-related parameters provided by the probes and sensors of the physical chamber, or by the related processes, and other parameter values that may be used to determine the current temperature of the physical chamber concerning various types of substrate processing performed within the chamber.

The first data set may be received by the digital twin device from, for example, sensors and probes, and/or via one or more communications interfaces. The communications interfaces are usually devices that are configured to facilitate communications between a digital twin device and a physical twin chamber (e.g., sensors and probes). In some configurations, the communications interfaces may facilitate communications between a plurality of digital twin devices and the corresponding plurality of twin chambers. Various configurations are described in FIG. 8-10.

The plurality of digital twin devices models interactions between chamber processes performed in one or more cluster tools utilized in the substrate processing sequence. Furthermore, the digital twin devices model the execution of a plurality of tasks performed by the chamber processes performed in one or more cluster tools utilized in the substrate processing sequence. Moreover, the digital twin devices model interactions between the pluralities of digital twin devices.

The first data set comprises direct measurements of physical processes collected and reported by probes and sensors implemented by the corresponding chamber processes, data collected and reported by internal sensors of the digital twin device, and data collected and reported by sensors monitoring substrates, including characteristics and properties of the substrates including responses of the substrates to processing performed by components of physical chambers. Therefore, the digital twin devices may also model the characteristics and properties of the substrates.

At block 1304, each digital twin device, of the plurality of digital twin devices, automatically generates the second data set that comprises the control inputs and automatically transmits the second data set to the corresponding chamber processes performed in one or more cluster tools for controlling the manufacturing of substrates by the corresponding chamber processes of the plurality of chamber processes.

The second data set is automatically generated by the digital twin device based on, at least in part, the first data set, and by executing the computational models, components, and subsystems of the digital twin device. The second data set may include, for example, the output generated by an AI-based application. The output may include, for example, control commands, control parameters, or instructions that may be used by operators of physical chambers, or by the physical chambers themselves, to fine-tune, or adjust, the control parameters of the physical chambers. the second data set (e.g., the output generated and provided by the AI application) may include updates (element 110 shown in FIG. 1) to the physical twin and may be generated by the digital twin based on, for example, calculated values (element 108 shown in FIG. 1), error information (element 112 shown in FIG. 1), and the like.

At block 1306, each digital twin device automatically transmits the second data set to the corresponding chamber processes for controlling the manufacturing of the substrates by the corresponding chamber processes performed in the one or more cluster tools utilized in the substrate processing sequence contemporaneously with receiving the first data set from the corresponding chamber processes performed in the one or more cluster tools utilized in the substrate processing sequence, and the like.

The specific details of the computation models of the digital twins, and the virtual models have been described before.

### Example Virtual Model of a Digital Twin

A virtual model implemented in a digital twin device is a digital model that may be constructed empirically from observed and measured data collected from, for example, a corresponding physical twin chamber (or chambers), and/or corresponding processes executed by the corresponding physical twin (or twins), corresponding substrates, and the like. The virtual model may be configured to evaluate the performance of the physical twin chamber relative to the chamber's expected or historical performance, or based on relevant prior data.

A virtual model may be also configured to compare the performance characteristics of the digital twin device and the physical twin chamber, as well as to evaluate the accuracy of the virtual model concerning the real-world results of the physical twin chamber. The virtual model may use, for example, the evaluation of the data from both the physical twin chamber and the digital twin device to create actionable insights to improve the performance of the physical twin chamber.

In some embodiments, a virtual model uses the Bayesian approach, in which each sub-model can retain its inherent variability and, when combined with other sub-models, may be representative of the real-world physical chambers.

A virtual model may also use machine learning techniques (e.g., a Markov chain approach, a Monte Carlo simulation, and the like) that can be used to generate thousands or tens of thousands of interpolation conditions to form a full process window map and also to map the process result sensitivity to input parameters.

In some embodiments, a virtual model uses synthetic training data that can be generated by applying, for example, various randomization techniques.

Implementation of a virtual model in a digital twin device allows tracking and controlling the performance of a physical twin chamber (e.g., chambers, cluster tools, a plurality of cluster tools, and substrates) over time and to, for example, compare and control multiple chambers (e.g., chambers, cluster tools, a plurality of cluster tools, and substrates) across a fleet. The implementation of the virtual model may include a collection of data describing the physical state of the physical twin chamber paired with a digital twin device, which may be implemented as a collection of integrated sub-system models of the physical twin.

A virtual model of a digital twin device may include computational models of chamber components and subsystems as well as the models of the corresponding physical and chemical actions and processes reported by the subsystems. The actions/processes may include, for example, heat transfer and transmission of electricity, EM radiation, chemical reactions, and the like. The modeling techniques may include a finite element analysis, CFD, direct computation, and solution of mathematical equations representing one or more attributes of the physical systems (e.g., physical motion, spatial temperature variation, current flow, voltage drop, electrical properties and/or characteristics, chemical concentration variation, pressure variation, generated plasma properties, vibration characteristics, generated E-fields, generated B-fields, etc.). The models may also include the models developed with lumped parameter system modeling networking tools such as thermal network models and network models designed to solve systems of electrical circuits. The implementations of the virtual models may provide real-time monitoring and intervention mechanisms for enhancing and improving the performance of the corresponding physical twin chamber (or chambers).

The virtual models are usually executed by processors of a digital twin and may be configured to host various physics or chemistry-based computational solutions. The models are usually configured to process the complex and critical characteristics of, for example, physical twins. In some implementations, a thermal digital twin model uses the Siemens AMESIM™ thermal network model to calculate, for example, a kit component and substrate temperature.

The virtual models may also be configured to provide updates for physical parameters and constants to be used by the model. The models can also incorporate the digital twin as its Bayesian entity with a graphical representation associated with a physical twin.

The virtual models are usually modular and expandable to incorporate new processes such as fluid flow models, surface chemistry reactions, electrical circuits, RF delivery, pedestal-to-substrate and wear, and plasma processes.

### Input and Output Data

Multiple types of data sets can be provided by both a physical twin chamber and a digital twin device. The provided data may be processed, evaluated, and analyzed to, for example, evaluate the performance of the physical twin chamber relative to its expected or historical performance. The data may also be processed to compare the digital and physical twins to each other to evaluate the accuracy of the virtual model executed by the digital twin to the real-world results provided by the physical twin chamber. The data may also be used to evaluate the outputs received from either, or both, physical and digital twins to create actionable insights to improve the physical twin chamber's performance.

The data used by digital-physical twins may be collected at multiple data rates, at multiple times, and may take various forms. The data collected, or received, from both the physical and digital twins may be stored and processed by the components configured to provide monitoring, calculation, and intervention in real-time.

The manner in which the data is collected, stored, processed, and analyzed may extend from single pairings of the physical and digital twins to multiple physical and digital twin pairs, and to form a fleet of twin pairs.

### Example Specification of Digital Twin Device

Product specifications for designing, building, and maintaining a digital twin allow creating the digital twin that is configured to simulate a physical chamber or system configured to manufacture substrates, including semiconductor substrates.

Typically, a digital twin device provides an output that may be used to, for example, control a corresponding physical twin, and perform an in-depth analysis of the processes executing in the physical twin. The output may also be ported to an impact analyzer to determine a baseline and foundation for obtaining and maintaining the accurate, functional, and robust physical twin.

Examples of twin-pair designs may include a single digital twin device that monitors and controls a single physical twin chamber. Another design may include a system of digital twins that monitors and controls one or more physical twin chambers. Other designs may include a fleet of digital twin devices with one-to-one correspondence with their real-world physical twin chamber counterparts. Other designs may include an arrangement in which digital twin devices are paired with corresponding processes executed by multiple process chambers of multi-chamber systems.

The purpose of designing and building a digital-physical twin pair is to establish a virtual model of the processes and functions of the physical twin chamber in real time. The corresponding digital twin device may be configured to make fast diagnostic evaluations of the performance of the physical twin chamber, accelerate the troubleshooting and resolution of faults, and take both proactive and corrective actions concerning the physical twin chamber to improve the performance and capabilities of the physical twin chamber.

The configuration of a digital twin device usually includes a virtual model of a corresponding physical twin chamber. The digital twin device communicates with the physical twin chamber and collects and processes various types of data, including the data associated with the physical twin chamber, the data associated with the virtual model, and other data related to controlling and maintaining the physical twin chamber. The digital twin device and physical twin chamber may communicate with each other via, for example, communications interfaces that provide the connectivity of data to and from the digital twin device and physical twin chamber.

### Probabilistic Graphical Model for a Digital Twin

The concept of digital-physical twins incorporates a probabilistic graphical model of a digital twin and its associated physical asset. The graphical model represents the structure of an asset-twin system by encoding the interaction and evolution of quantities defined, for example, in FIG. 1-2. In particular, the model encodes the end-to-end digital twin data-to-decisions flow, from sensing through inference and assimilation to action.

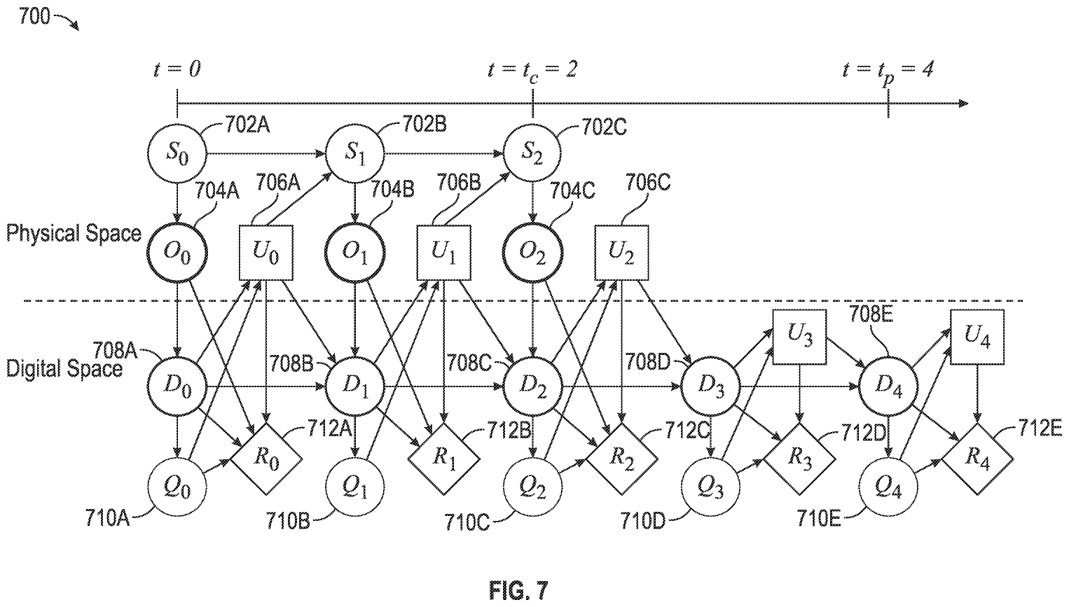

FIG. 7 is an example dynamic digital network 700 according to some embodiments of the present principles. The dynamic digital network captures the probabilistic graphical model described above. More specifically, a dynamic decision network mathematically represents a physical asset and its digital twin.

In FIG. 7, nodes shown with bold outlines are observed quantities (i.e., they are assigned deterministic values), while other quantities are estimated (typically represented by probability distributions). Directed edges represent conditional dependence. The control nodes are decision nodes. The number of nodes depicted in FIG. 7 is not limiting; depending on the implementation, other dynamic digital networks may have more or fewer nodes.

Dynamic digital network 700 depicted in FIG. 7 includes several state nodes (702A, 702B, 702C), several observation nodes (704A, 704B, 704C), several digital state nodes (708A, 708B, 708C), several predicted quantities of interest nodes (710A, 710B, 710C, 710D, 710E), several reward nodes (712A, 712B, 712C, 712D), and several control input nodes (706A, 706B, 706C).

The state nodes, observation nodes, and control input nodes are components of the physical space (i.e., they correspond to a physical twin), while the digital state nodes, predicted quantities of interest nodes, and reward nodes are components of the digital space (i.e., they correspond to a digital twin). The stochastic processes executed by dynamic digital network 700 are identified along a time axis with the corresponding time steps (i.e., t=0, t=t_{c}=2, t=tₚ=4), and so on.

The model presented in FIG. 7 corresponds to a dynamic decision network, and more specifically, a dynamic Bayesian network with the addition of decision nodes. FIG. 7 shows the graph unrolled from the initial time step, t=0, to the current time step, t=t_{c}, and into the future to the prediction horizon, t=tₚ. Nodes in the graph are random variables representing each quantity at discrete points in time. For example, the digital state at time step t is estimated probabilistically by defining the random variables Dₜ˜p(dₜ). Edges in the graph represent dependencies between variables, encoded via either a conditional probability density or a deterministic function.

The graphical model depicted in FIG. 7 serves as a mathematical counterpart to the conceptual model described in FIG. 1. The upper left-to-right path in FIG. 7 represents the time evolution of the physical asset state, represented by the random variables Sₜ˜p(sₜ), while the lower path represents the time evolution of the digital state, represented by the random variables Dt.

The graphical model encodes the tight two-way coupling between an asset and its digital twin. Information flows from the physical asset to the digital twin in the form of observational data, Oₜ, which are assimilated to update the digital state. Using the updated digital state, the models comprising the digital twin are used to predict quantities of interest, modeled at time t as Oₜ˜p(qₜ).

Information flows from the digital twin back to the physical twin in the form of control inputs, Uₜ, which are informed by the digital state and computed quantities of interest. These quantities all influence the reward for the time step, Rₜ˜p(rₜ).

### Example Graphical User Interface

Interactions between digital and physical twins in individual configurations and fleet-system configurations may be represented using various user interfaces, including graphical user interfaces (GUIs).

One exemplary GUI may depict a graph of the physical and digital twin showing labels to identify relationships between the physical and digital twin elements. According to another example, a GUI may depict a dashboard showing a comparison between physical twins and digital twins to allow for a comparison of time series data, and summary data as computed by time series data analysis. According to another example, a GUI may depict side-by-side maps of measured metrology data and predicted film property data allowing for comparison, subtraction, addition, decomposition (radial, planar, residual), and overlay.

Other exemplary GUIs may depict a fleet comparison, in which, for example, N chambers or systems can be reviewed and adjusted during the startup. To generate this type of visualization, it might be more effective to connect all systems at the same time. However, if it is impossible to connect the setup computer to more than one system, then the rest of the fleet's physical twin data must be visualized as they are imported one by one.

### Example Architecture of a Thermal Digital Twin for Substrate Manufacturing

The thermal processes involved in substrate manufacturing and the difficulties in maintaining the accuracy of the thermal processes were some of the reasons for developing the concept of digital-physical twins. The description of the thermal processes themselves and their details are beyond the scope of the present description. Some details about the thermal processes are provided in, for example, U.S. Pat. No. 10,651,095B2, U.S. Pat. No. 11,158,527B2, and U.S. Pat. No. 11,515,218B2.

FIG. 8 is an example architecture 800 of a digital twin for substrate manufacturing, such as a thermal digital twin. The architectures of the thermal digital twin may vary from implementation to implementation, and the architecture depicted in FIG. 8 is used merely as an example. Certain details of the architecture are not described in FIG. 8 as they may depend on the implementation. The example architecture may include a local server 804 (AIT) configured close to the wafer processing system for faster edge computing. There is also a larger central server 806 (AIC) that communicates to the smaller local server and aggregates information from the local servers to allow for fleet-level comparisons as well as fleet-level updating of local models. AIT and AIC are in part Applied Materials Inc.’ marketing acronyms. Other related architectural terms include an Actionable Insight “X”ccelerator (Aix) developed by a team of engineers of the AIx Center of Excellence within Applied Materials, Inc. An AIx enabled factory has AITs on each tool and an AIC in a central data center. The AITs are interfaced to the tools to allow data transfer and integrated to the tools for providing feedback. The data results processed by Algos or ML Models on the AITs are sent via a storage service pipeline to the AIC which can see all the inbound results for the entire fleet. The AIC Algos or ML Models can then further process the results to extract fleet-wide insights for display on dashboards or transmission to factory automation. The AIC provides a central database for processed results from AITS, not raw time-trace data from the tools. The AIC also provides software management services to the fleet of Algos and ML Models on the AITs and AIC, including installation, configuration, calibration, training and monitoring.

Other terms include Actionable Insight-Tool (AI-T) and Actionable Insight-Central (AI-C). AI-T and AI-C are the server constructions that the AIx team has designed. AIC 806 may execute various components, including a virtual machine (VM) communicating with a framework 808, which in turn may include training data, workflow data, algorithms, summary, and the like. AIC 806 may also include a management unit, an AIC database, a Tableau, a user interface 810, storage, and the like. The software package “Tableau” may be used to design the dashboards for ease of use for data review. Tableau is an example of plotting and graphing software. Another example of such plotting/graphing software is “React.”

AIT 804 may include various components that are associated with a physical twin chamber, such as, for example, a processing chamber, a cluster tool, or a series of processing chambers or cluster tools. The AI-T is usually a small form factor local server (1UBlade in this configuration) that primarily functions as the interface between the AI-C and the existing computers (such as control servers). The AI-T can also host edge computing modules for fast computation and updating closer to the tool. The AI-C is used in reference to cluster tools since the AI-C could host the fleet of digital twins on the AI-C.

The types of components and their naming convention usually depend on the implementation. The implementation alternatives are not described herein. In this configuration, the AIT may include computer-implemented instructions that are performed by use of a controller that is associated with the physical twin chamber.

AIC 806 may communicate with AIT 804 via, for example, a front-end interface 802, and one or more tool networks. The transfer of information between the AIC and AIT can be used to improve the control of the physical twin chamber as part of the processes performed by a physical and digital twin pair.

Other implementations of the thermal process for substrate manufacturing may also be implemented.

### Example Thermal Digital Twin

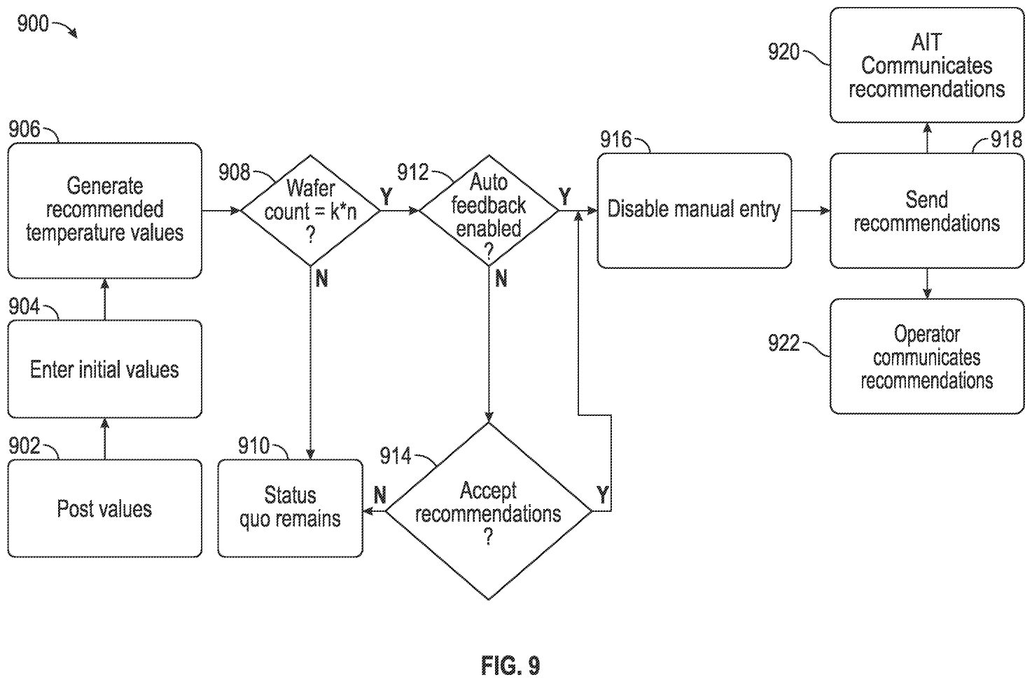

FIG. 9 is an example architecture 900 of a digital twin, such as a thermal digital twin for substrate processing according to some embodiments of the present principles. The depicted example is one of many example implementations provided herein for general reference. Certain details of the workflow are omitted herein for the clarity of the description.

FIG. 9 is described in terms of actions that both an operator and a digital twin perform. At block 902, an operator resets/posts the initial values of the process parameters that are to be used in the physical twin chamber to their corresponding baseline values.

At block 904, the operator enters the initial values into a physical and digital twin-chamber configuration. The digital twin uses the initial values as input for executing the twin's modeling and/or AI-based application(s).

At block 906, the digital twin generates and displays recommended process parameters, such as temperature parameter values for the thermal process. These values are output generated by the digital twin based on the initial values. As described in FIG. 7, the output may be generated by executing the modeling and/or AI-based application.

At block 908, the digital twin checks whether a substrate count is k*n. If it is, then instructions of block 912 are performed; otherwise, at block 910 the status quo is maintained.

At block 912, the digital twin checks if auto feedback is enabled. If it is, then at block 916, the manual data entry to the tool is disabled; otherwise, at block 914 the operator determines whether to accept the thermal digital twin recommendations and if so, instructions at block 916 are performed; otherwise, the status quo is maintained.

At block 918, the digital twin sends recommendations to a central location accessible to an artificial intelligence tool, and the like.

The recommendations are communicated to front end server (FES) either by the artificial intelligence tool at block 920 or by an operator team (E2/APC) at block 922.

The remaining details are specific to a particular implementation and their description is omitted herein.

### Example Flow Digital Twin Model

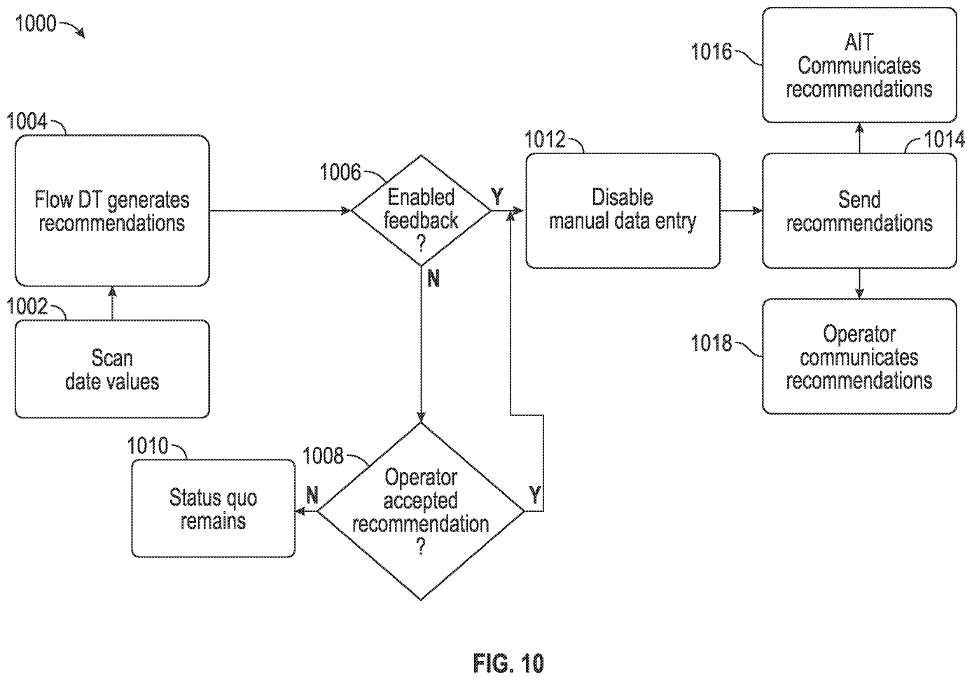

FIG. 10 is an example of a flow digital twin according to some embodiments of the present principles. The depicted flow digital twin model is one of many example implementations and its description is provided herein as a general reference. Certain details of the flow digital twin model are omitted herein for the clarity of the description. The flow digit twin may be used to monitor and control the power flow and supply in the substrate processing.

The flow is described in terms of actions that a customer technician, an operator, and a flow digital twin may perform. At block 1002, a customer technician scans parts and other data into a digital twin system.

At block 1004, a flow digital twin generates and displays recommended flow rates and other initial values based on the use of modeling and/or AI-based application(s).

At block 1006, the flow digital twin tests whether auto feedback is enabled. If it is, then at block 1012, the flow digital twin disables the manual data entry on the tool; otherwise, at block 1008, the operator tests whether the flow digital twin's recommendations can be accepted. If they can, then instructions at block 1012 are performed. Otherwise, the status quo is maintained in block 1010.

At block 1014, the flow digital twin sends recommendations to a central location accessible to an artificial intelligence tool, and the like.

The recommendations are either communicated to file storage by the artificial intelligence tool at block 1016, or by an operator at block 1018.

The remaining details are specific to a particular implementation and their description is omitted herein.

Embodiments by the present principles may be implemented in hardware, firmware, software, or any combination thereof. Embodiments may also be implemented as instructions stored using one or more computer-readable media, which may be read and executed by one or more processors. A computer-readable medium may include any mechanism for storing or transmitting information in a form readable by a machine (e.g., a computing platform or a “virtual machine” running on one or more computing platforms). For example, a computer-readable medium may include any suitable form of volatile or non-volatile memory. In some embodiments, the computer-readable media may include a non-transitory computer-readable storage medium.

While the foregoing is directed to embodiments of the present principles, other and further embodiments of the principles may be devised without departing from the basic scope thereof.

What is claimed is:

1. A digital twin system for controlling a physical twin chamber configured to process substrates, the digital twin system comprising:
a digital twin device determining characteristics of a physical twin chamber and generating control inputs for controlling the physical twin chamber;
wherein the digital twin device comprises one or more computational models for determining the characteristics of the physical twin and for generating the control inputs;
wherein the digital twin device determines a first data set associated with the physical twin chamber;
wherein the first data set comprises process data collected by sensors configured to measure attributes of the physical twin chamber;
wherein the digital twin device automatically generates a second data set based on the generated control inputs and transmits the second data set to the physical twin chamber for controlling the process performed on the substrates by the physical twin chamber; and
wherein the second data set is automatically generated by the digital twin device based on, at least in part, the first data set, and by executing the one or more computational models of the digital twin device.

2. The digital twin system of claim 1, wherein the digital twin generates the second data set and transmits the second data set to the physical twin chamber contemporaneously with receiving the first data set from the physical twin chamber.

3. The digital twin system of claim 1, wherein the one or more computation models of the digital twin device comprise a model of the physical twin chamber;
wherein the model is configured to model one or more of: fluid dynamics, direct Monte Carlo (DSMC) simulation, magneto-hydrodynamic particle-in-cell simulations, EM solvers, optical modeling tools, or direct computation of mathematical equations representing an attribute of the physical twin chamber; and
wherein the digital twin device performs, using at least the model, real-time monitoring and controlling of the physical twin chamber.

4. The digital twin system of claim 1, wherein the one or more computational models of the digital twin device include one or more of: models of electrical, mechanical, fluid flow, or vacuum environment characteristics.

5. The digital twin system of claim 1, wherein
the digital twin device models the characteristics and the processes of the physical twin chamber using models that include one or more of: a lumped parameter system modeling networking tools, network models for solving systems of electrical circuits, or derivatives of network models;
the first data set includes characteristics and properties of the substrate including responses of the substrate to processing performed by components of the physical twin chamber; and
the digital twin models the characteristics and properties of the substrate.

6. The digital twin system of claim 3, wherein the model is constructed empirically from measured data from the physical twin chamber.

7. The digital twin system of claim 3, wherein the model of the digital twin device:
evaluates performance of the physical twin chamber relative to its expected or historical performance as established by prior data;
compares performance characteristics of the digital twin device and the physical twin chamber to evaluate accuracy of the model to results of the physical twin chamber; and
uses evaluation of the data from both the physical twin chamber and the digital twin device to create actionable insights to improve performance of the physical twin chamber.

8. A method for controlling a physical twin chamber for substrate processing, the method comprising:
determining, by a digital twin device, a first data set associated with a physical twin chamber;
wherein the digital twin device comprises one or more computational models for determining characteristics of the physical twin and for generating the control inputs;
wherein the first data set comprises direct measurement of physical processes collected and reported by sensors implemented in the physical twin chamber and data collected and reported by internal sensors of the digital twin device;
automatically generating, by the digital twin device, a second data set that comprises the control inputs, and transmitting the second data set, by the digital twin device, to the physical twin chamber for controlling substrate processing by the physical twin chamber; and
wherein the second data set is automatically generated by the digital twin device based on, at least in part, the first data set, and by executing the one or more computational models of the digital twin device.

9. The method of claim 8, wherein the digital twin generates the second data set and transmits the second data set to the physical twin contemporaneously with receiving the first data set from the physical twin chamber.

10. The method of claim 8, wherein the one or more computation models of the digital twin device comprise a model of the physical twin chamber;
wherein the model is configured to model one or more of: fluid dynamics, direct Monte Carlo (DSMC) simulation, magneto-hydrodynamic particle-in-cell simulations, EM solvers, optical modeling tools, or direct computation of mathematical equations representing an attribute of the physical twin chamber; and
wherein the digital twin device performs, using at least the model, real-time monitoring and controlling of the physical twin chamber.

11. The method of claim 8, wherein the one or more computational models of the digital twin device include one or more of: models of electrical, mechanical, fluid flow, or vacuum environment characteristics;
wherein the one or more computations models capture corresponding chemical actions reported by subsystems; and
wherein the corresponding and chemical actions include one or more of: heat transfer, transmission of electricity, electrical pulses, EM radiation, chemical reactions, material phase, erosion, or wear due to physical contact.

12. The method of claim 8, wherein the digital twin device models the characteristics and the processes of the physical twin chamber using models that include one or more of: a lumped parameter system modeling networking tools, network models for solving systems of electrical circuits, or derivatives of network models;
wherein the first data set includes characteristics and properties of the substrate including responses of the substrate to processing performed by components of the physical twin chamber; and
wherein the digital twin models the characteristics and properties of the substrate.

13. The method of claim 10, wherein the model is constructed empirically from measured data from the physical twin chamber.

14. The method of claim 10, wherein the model of the digital twin device:
evaluates performance of the physical twin chamber relative to its expected or historical performance as established by prior data;
compares performance characteristics of the digital twin device and the physical twin chamber to evaluate accuracy of the model to results of the physical twin chamber; and
uses evaluation of the data from both the physical twin chamber and the digital twin device to create actionable insights to improve performance of the physical twin chamber.

15. A substrate processing system, comprising:
a digital twin device determining characteristics of a physical twin chamber and generating control inputs for controlling the physical twin chamber;
wherein the digital twin device comprises one or more computational models for determining the characteristics of the physical twin and for generating the control inputs;
wherein the digital twin device comprises a processor and a memory coupled to the processor, the memory having stored instructions executable by the processor to:
determine, by the digital twin device a first data set associated with the physical twin chamber;
wherein the first data set comprises direct measurement of physical processes collected and reported by sensors implemented in the physical twin chamber and data collected and reported by internal sensors of the digital twin device;
automatically generate, by the digital twin device, a second data set that comprises the control inputs, and transmit the second data set, by the digital twin device, to the physical twin chamber for substrate processing by the physical twin chamber; and
wherein the second data set is automatically generated by the digital twin device based on, at least in part, the first data set, and by executing the one or more computational models of the digital twin device.

16. The substrate processing system of claim 15, wherein the digital twin generates the second data set and transmits the second data set to the physical twin contemporaneously with receiving the first data set from the physical twin chamber.

17. The substrate processing system of claim 15, wherein the one or more computation models of the digital twin device comprise a model of the physical twin chamber;
wherein the model is configured to model one or more of: fluid dynamics, direct Monte Carlo (DSMC) simulation, magneto-hydrodynamic particle-in-cell simulations, EM solvers, optical modeling tools, or direct computation of mathematical equations representing the physical twin chamber;
wherein the digital twin device performs, using at least the model, real-time monitoring and controlling of the physical twin chamber; and
wherein the digital twin device monitors and controls the physical twin chamber by executing one or more fast-running network models and empirically built relational data models.

18. The substrate processing system of claim 15, wherein the one or more computational models of the digital twin device include one or more of: models of electrical delivery, models of mechanical delivery, models of fluid delivery, or models of vacuum systems;
wherein the one or more computations models capture corresponding physical and chemical actions reported by subsystems; and
wherein the corresponding and chemical actions include one or more of: heat transfer, transmission of electricity, electrical pulses, EM radiation, chemical reactions, material phase, erosion, or wear due to physical contact.

19. The substrate processing system of claim 15, wherein the digital twin device models the characteristics and the processes of the physical twin chamber using models that include one or more of: a lumped parameter system modeling networking tools, network models for solving systems of electrical circuits, or derivatives of network models;
wherein the first data set includes characteristics and properties of the substrate including responses of the substrate to processing performed by components of the physical twin chamber; and
wherein the digital twin models the characteristics and properties of the substrate.

20. The substrate processing system of claim 17, wherein the model is constructed empirically from measured data from the physical twin chamber.
